(19) United States
(12) Patent Application Publication
(10) Pub. No.: US 2004/0041269 A1
(43) Pub. Date: Mar. 4, 2004

(54) Semiconductor device and manufacturing method thereof

(75) Inventor: Sadayuki Ohnishi, Kanagawa (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/646,709

(22) Filed: Aug. 25, 2003

(30) Foreign Application Priority Data
Aug. 30, 2002 (JP) 255134/2002

(51) Int. Cl. H01L 23/48

(52) U.S. Cl. 257/758

(57) ABSTRACT

An SiCN layer 108, BCB layer 110 and MSQ layer 112 are deposited in this sequence on a copper interconnect line constituted by a barrier metal layer 104 and a copper layer 106. The BCB layer 110 is formed by plasma polymerization of a monomer containing a divinylsiloxane bisbenzocyclobutene unit.

This application is based on Japanese patent application NO.2002-255134, filed on Aug. 30, 2002, the content of which is incorporated hereinto by reference.

### BACKGROUND OF THE INVENTION

1. Field of the Invention

The present invention relates to a technique for improving adhesion of an interlayer dielectric film utilizing a low dielectric constant insulating material.

2. Description of the Related Art

Recently, as a semiconductor device has been increasingly required to operate at higher speed, various efforts are more intensely focused on the replacement of silicon oxide (dielectric constant K=approx. 4.3) making up an interlayer dielectric film with a material having a lower dielectric constant and then the reduction in parasitic capacitance between interconnect lines. HSQ, MSQ, and organic resin materials containing an aromatic compound, which have a dielectric constant of approx. 3, can be employed as the low dielectric constant insulating material, however for achieving a still lower dielectric constant, porous materials that constitute a less dense film having minute pores therein or having a spaced monomer molecule structure are being developed.

Among such porous materials, some have been reported to have a dielectric constant as low as approx. 2.2. Employing such materials as an interlayer dielectric film can reduce cross talk among interconnects, thereby accomplishing faster performance of a device.

However, a film constituted by a low dielectric constant insulating material is prone to cause imperfect adhesion with a film formed thereon or thereunder. Especially when a porous material is employed as an insulating film, the problem of insufficient adhesion is significantly serious because of lower film density.

The JP-A No.2001-326222 discloses a technique for solving the problem of imperfect adhesion of low dielectric constant film. FIG. 1 is a schematic cross-sectional drawing of an interconnect structure described as a related art in this publication.

This interconnect structure is constituted by an interlayer dielectric film consisting of a silicon nitride layer 1 on which an MSQ layer 2 and a silicon oxide layer 4 are deposited in this sequence, and a copper interconnect line consisting of a barrier metal layer 5 and a copper layer 6 formed in the interlayer dielectric film. In this case, while the MSQ layer 2 consists of an organic material the silicon oxide layer 4 is an inorganic material, therefore imperfect adhesion tends to take place between these materials, including exfoliation in an extreme case. For solving such problem, this publication proposes to interleave an MHSQ (methyl-hydrogen-silsesquioxane) layer 3 between the MSQ layer 2 and the silicon oxide layer 4 as shown in FIG. 2, in order to improve the adhesion. In addition to the example of FIG. 2 in which the MHSQ layer is employed, this publication also offers a polysiloxane compound having an Si—H group in its molecule, presuming that a reason of improved adhesion due to employing such material is that the Si—H group is dehydrogenated to generate reactive area, thereby reacting with the upper or lower dielectric film.

On the other hand, the imperfect adhesion also takes place at a different position than those cited in the above publication, in case of employing a low dielectric constant material such as MSQ. FIG. 3 is a schematic cross-sectional drawing of a conventional interconnect structure in which the MSQ is used. This structure consists of an SiCN layer 100 on which an MSQ layer 102, an SiCN layer 108 and another MSQ layer 112 are deposited in this sequence. In the MSQ layer 102 a wiring trench is formed, in which a copper interconnect line consisting of a barrier metal layer 104 and a copper layer 106 is formed. In such interconnect structure, imperfect adhesion tends to occur delamination at an interface between the SiCN layer 108 and the MSQ layer 112, in an extreme case. A probable reason of such phenomenon is that a methyl group contained in the MSQ layer is hydrophobic, and therefore not sufficiently affinitive with the SiCN.

It may be an option to substitute a material in the SiCN layer 108 with something else for resolving the imperfect adhesion. However, since the SiCN layer 108 is also serving as a copper diffusion barrier constituting the copper interconnect line, a certain restriction is inevitably imposed when substituting a material. The JP-A No.2001-326222 is not offering any solution of the imperfect adhesion at a lower interface of the MSQ layer. Besides, the technique of employing the Si—H group for improving adhesion described in this publication has a downside that may be damaged to absorb moisture by plasma ashing or wet stripping solution after etching process since the Si—H group is relatively reactive, resulting in an increase of dielectric constant. Further, when employing a porous MHSQ layer to reduce dielectric constant, the plasma ashing gas or wet stripping solution is introduced through the pores, which may cause deterioration of film quality such as moisture absorption or increase in dielectric constant.

### SUMMARY OF THE INVENTION

In view of the foregoing problem, the present invention has been conceived to increase adhesion between a low dielectric constant film and adjacent layers without increase in dielectric constant of an interlayer dielectric film.

The present invention provides a semiconductor device comprising a semiconductor substrate; and an interlayer dielectric film formed on the semiconductor substrate; wherein the interlayer dielectric film comprises a lamination including an adhesive film constituted essentially by a silicon-based compound having an aromatic ring in a molecule thereof, and a low dielectric constant film constituted essentially by an organic low dielectric constant material having a specific dielectric constant not greater than 4 formed in contact with the adhesive film.

In this semiconductor device, an adhesive film is provided in contact with a low dielectric constant film. Since the adhesive film is constituted by a silicon-based compound having an aromatic ring in its molecule, the adhesive film has high affinity with the organic material constituting the low dielectric constant film. Consequently, the low dielectric constant film and the adhesive film are firmly adhered.

The invention also provides a manufacturing method of a semiconductor device comprising the steps of forming on a semiconductor substrate an adhesive film constituted essentially by a silicon-based compound having an aromatic ring in a molecule thereof; and forming a low dielectric constant film constituted essentially by an organic low dielectric constant material having a specific dielectric constant not greater than 4 over the adhesive film.

The invention also provides a manufacturing method of a semiconductor device comprising the steps of forming on a semiconductor substrate a low dielectric constant film constituted essentially by an organic low dielectric constant material having a specific dielectric constant not greater than 4; and forming an adhesive film constituted essentially by a silicon-based compound having an aromatic ring in a molecule thereof over the low dielectric constant film.

By such manufacturing method of a semiconductor device according to the invention, a semiconductor device in which a low dielectric constant film and an adhesive film are firmly adhered can be stably manufactured.

According to the invention, it is preferable that the aromatic ring contained in the silicon-based compound constituting the adhesive film is a fused ring. As a result, affinity of the adhesive film with the organic material constituting the low dielectric constant film is further increased, thus achieving further improvement of adhesion between the low dielectric constant film and the adhesive film. A benzocyclobutene unit and the like may be employed as the fused ring.

It is preferable that the silicon-based compound constituting the adhesive film contains a silylene unit in its molecule. The silylene unit referred to herein represents a unit described as SiR1R2—(where R1 and R2 are a hydrogen group or a hydrocarbon group), and the molecule may contain a plurality of such units. Such silylene unit introduced in a molecule facilitates relaxation of stress applied in the adhesive film.

The silicon-based compound constituting the adhesive film may be a polymer. For example, a polymer can be obtained by polymerizing a monomer containing a divinylsiloxane bisbenzocyclobutene unit. Thermal polymerization or plasma polymerization can be employed for this purpose, among which the plasma polymerization is more preferable because thermal resistance of the attained polymer remarkably increases. It is also possible to perform, upon forming the adhesive film, plasma treatment of the adhesive film and then form the low dielectric constant film. In this way the adhesion is further increased. Further, in case of forming both the adhesive film and the low dielectric constant film by CVD method, the manufacturing process can be simplified, since the series of process can be successively performed holding the semiconductor substrate in a vacuum.

According to the invention, it is preferable to employ an organic low dielectric constant material that has a low dielectric constant and high heat resistance, such as SiOC and so forth.

Also, it is preferable to employ a compound of a molecule structure substantially free from a Si—H bond as the organic low dielectric constant material, from a viewpoint of restraining increase of dielectric constant due to a plasma ashing or wet stripping damage during the process. For example, methylsilsesquioxane and the like may be preferably employed.

The lamination may be constituted in any order provided that the adhesive film and the low dielectric constant film are in mutual contact, however better adhesion is attained by depositing the adhesive film first, and then the low dielectric constant film.

According to the invention, the manufacturing method may further comprise the steps of forming a metal wiring on a semiconductor substrate and forming the lamination constituted as above. In this case, the adhesive film can be deposited in contact with the metal wiring and further on the adhesive film the low dielectric constant film can be layered. Otherwise, it is also possible to form a metal diffusion barrier on the metal wiring, and deposit the adhesive film and the low dielectric constant film thereon in this sequence. As a result of providing such lamination on the metal wiring, adhesion of the interlayer dielectric film can be improved while preventing diffusion of the metal out of the metal wiring.

In case of adopting a constitution including the metal wiring, a cap metal may be provided on an upper surface of the metal wiring, and the adhesive film may be formed in contact with the upper surface. The cap metal serves to restrain diffusion of the metal constituting the metal wiring, thereby preventing stress migration of the metal wiring. As a result of forming the adhesive film over the cap metal, since the diffusion barrier on the metal wiring can be omitted, parasitic capacitance among the interconnects can be reduced.

According to the invention, the manufacturing method may further comprise the steps of performing UV treatment or plasma treatment of the adhesive film after the step of forming the adhesive film, and forming the low dielectric constant film. As a result, the low dielectric constant film and the adhesive film are more firmly adhered.

### BRIEF DESCRIPTION OF THE DRAWINGS

FIG. 1 is a schematic cross-sectional drawing of a conventional interconnect structure;

FIG. 2 is a schematic cross-sectional drawing of a conventional interconnect structure;

FIG. 3 is a schematic cross-sectional drawing of a conventional interconnect structure;

FIG. 4 is a schematic cross-sectional drawing of an interconnect structure according to the present invention;

FIG. 5 includes schematic cross-sectional drawings showing a manufacturing method of the interconnect according to the invention;

FIG. 6 includes schematic cross-sectional drawings of an interconnect structure according to the invention;

FIG. 7 is a schematic cross-sectional drawing of an interconnect structure according to the invention;

FIG. 8 includes schematic cross-sectional drawings showing a manufacturing method of the interconnect according to the invention;

FIG. 9 is a schematic cross-sectional drawing of an interconnect structure according to the invention;

FIG. 10 includes schematic cross-sectional drawings showing a manufacturing method of the interconnect according to the invention;

FIG. 11 includes schematic cross-sectional drawings for explaining an evaluating method of interlayer adhesion;

FIG. 12 is a bar graph showing an evaluation result of interlayer adhesion; and

FIG. 13 is a schematic cross-sectional drawing of a multilayer interconnect structure.

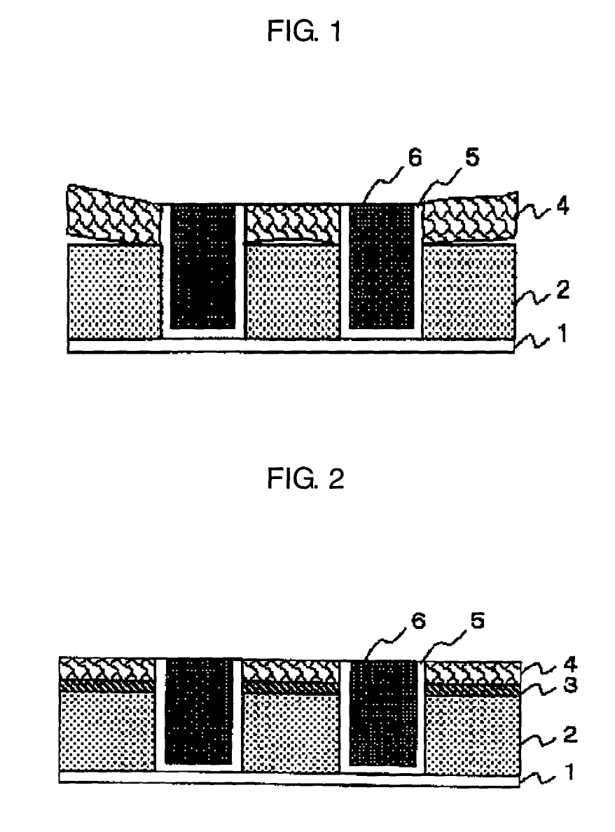

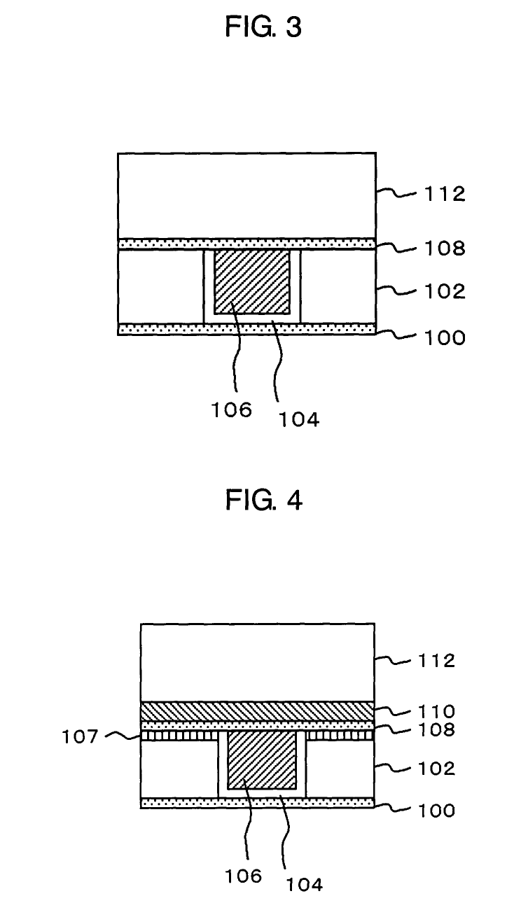

### DESCRIPTION OF THE PREFERRED EMBODIMENTS

Referring to the accompanying drawings, preferable embodiments of the present invention shall be described as follows.

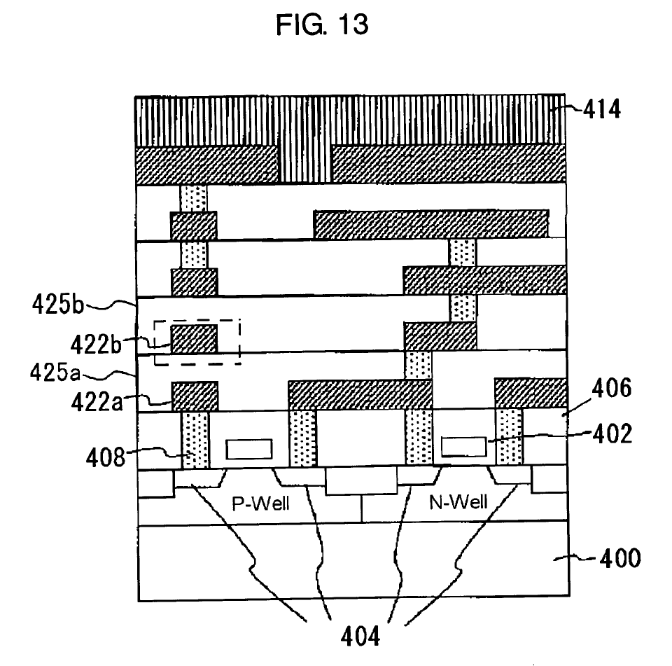

In a logic system device etc., a multilayer interconnect structure (interconnect stack) including a plurality of interconnect layers is often employed, as shown in FIG. 13. In such interconnect structure, a transistor constituted by a gate electrode 402 and an impurity diffusion layer 404 is formed in a first layer 406 and a silicon substrate 400, and interlayer dielectric films 425a, 425b are deposited in this sequence on the transistor. In these interlayer dielectric films, copper interconnect lines 422a, 422b are formed respectively. The copper interconnect line 422a and the impurity diffusion layer 404 are connected through a contact hole 408. A passivation layer 414 is deposited on an uppermost level of the interconnect stack. How the copper interconnect line 422b in this multilayer interconnect structure is constructed and manufactured will l be described in detail referring to some examples. In the following description, “BCB” refers to “benzocyclobutene”.

First Embodiment

FIG. 4 is a schematic cross-sectional view of an interconnect structure according to this embodiment. As shown, an MSQ layer 102, SiO.sub.2 layer 107, SiCN layer 108, BCB layer 110 and another MSQ layer 112 are deposited in this sequence on an SiCN layer 100, and a copper interconnect line constituted by a barrier metal layer 104 and a copper layer 106 is formed in the MSQ layer 102. The barrier metal layer 104 is formed by depositing TaN and then Ta. The SiCN layers 100, 108 serve as a copper diffusion barrier. These SiCN layers may be replaced with other layers of, for example, SiN, SiC. The BCB layer 110 formed between the SiCN layer 108 and the MSQ layer 112 is formed by plasma polymerization. Thickness of the respective layers of the interconnect structure shown in FIG. 4 may, for example, be as follows:

SiCN layer 100 20 to 100 nm

MSQ layer 102 200 to 400 nm

copper layer 106 200 to 400 nm

SiO.sub.2 layer 107 50 to 200 nm

SiCN layer 108 20 to 100 nm

BCB layer 110 20 to 200 nm

MSQ layer 112 300 to 1000 nm

Since the BCB layer 110 is highly adhesive to both of the SiCN layer 108 and the MSQ layer 112, weak adhesion, conventionally observed, between the SiCN layer 108 and the MSQ layer 112 can be avoided. Also, since the MSQ layer 112 formed above the copper interconnect line has an extremely low specific dielectric constant, parasitic capacitance between a certain interconnect line and other interconnect lines disposed below/above or on either side of and adjacent the certain interconnect line can be effectively reduced.

Further, similarly to the SiCN layer 108, the BCB layer 110 is capable of preventing diffusion of the copper and therefore, the SiCN layer can be formed thinner by a thickness of the BCB layer that is inserted between the SiCN layer 108 and the MSQ layer 112. For example, when employing a conventional structure without the BCB layer, the SiCN layer needs to have a thickness of approx. 50 nm or more in order to prevent copper diffusion, however, inserting the BCB layer having a thickness of 25 nm between the SiCN layer 108 and the MSQ layer 112 insersion prevents copper diffusion even when the SiCN layer is formed to have a thickness of 25 nm. In this way, forming a thinner SiCN layer (k=4.8) and inserting a BCB layer having a lower dielectric constant of 2.7 between the associated layers reduces parasitic capacitance between interconnect lines.

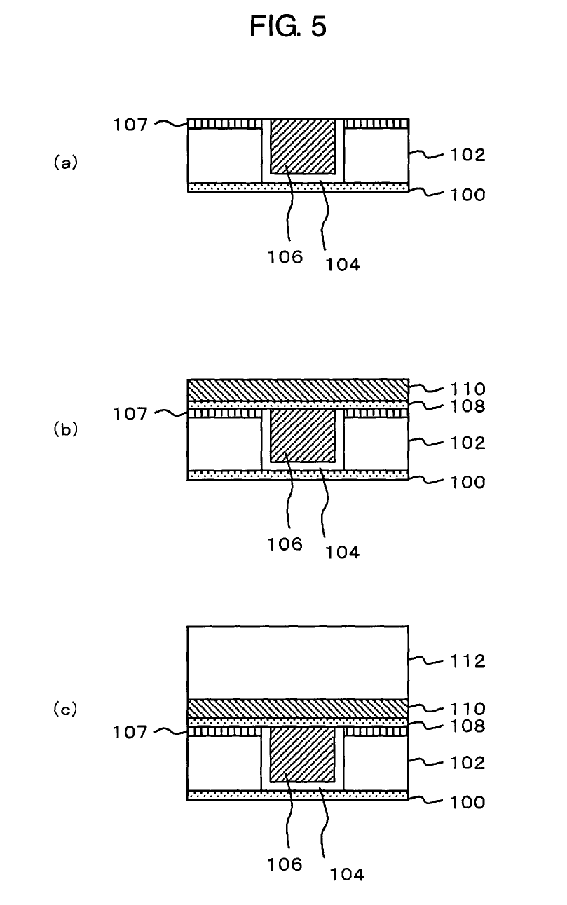

How the interconnect structure shown in FIG. 4 is constructed will be described. FIGS. 5A-C are schematic cross-sectional views showing process steps illustrative of how the interconnect structure of FIG. 4 is constructed. After the MSQ layer 102 and SiO.sub.2 layer 107 are first formed in this sequence on the SiCN layer 100, the copper interconnect line constituted by the barrier metal layer 104 and the copper layer 106 is formed using the known Damascene process (FIG. 5A). The reason why the SiO.sus.2 layer 107 is provided is that adhesion between the copper diffusion barrier (the SiCN layer 108 in this embodiment) and a structure below the barrier needs to be increased and damage imposed on the MSQ layer 102 and caused by plasma charging during a resist ashing process needs to be avoided. Then the SiCN layer 108 is formed over the substrate, on which in turn, the BCB layer 110 is formed (FIG. 5B).

The BCB layer 110 can be formed by plasma polymerization, spin coating and so forth. In this case, employment of plasma polymerization ensures that the BCB layer provides a higher durability against thermal degradation than that formed by spin coating. Specifically, the BCB layer formed by spin coating is not degraded under up to approx. 350.degree. C. atmosphere, while the BCB layer formed by by plasma polymerization is not degraded under up to approx. 400.degree. C. atmosphere.

In this embodiment, explanation is made of a BCB layer formed by plasma polymerization. In this embodiment, divinylsiloxane benzocyclobutene monomer having a chemical structure represented by the following chemical formula is vaporized, and the vaporized monomer is introduced into a plasma in, for example, He to perform plasma polymerization, thereby producing the BCB layer 110.

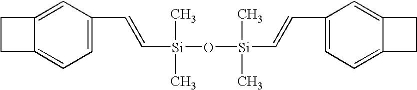

How to form a BCB layer using plasma polymerization is disclosed in detail in the JP-A No.2000-100803. In a plasma polymerization process, for example, BCB monomer supplied at 0.1 g/min is vaporized at a temperature of 200.degree. .C.. and the monomer is supplied with a He carrier gas stream at a flow rate of 500 sccm to a reaction chamber and BCB monomer gas is introduced into He plasma atmosphere within the chamber through a shower head to which an RF power of 13.56 MHz is applied, and then, a plasma-polymerized BCB layer is grown on a substrate heated to 400.degree. C.. The plasma-polymerized BCB layer formed as described above has a specific dielectric constant of 2.5 to 2.6, which is lower than that of a BCB layer formed by thermal polymerization. Formation of the BCB layer through the above-mentioned plasma polymerization is ensured by measurement of the BCB layer using a Fourier transform infrared spectrometer.

The BCB layer formed by plasma polymerization is considered to have a structure represented by the following formula.

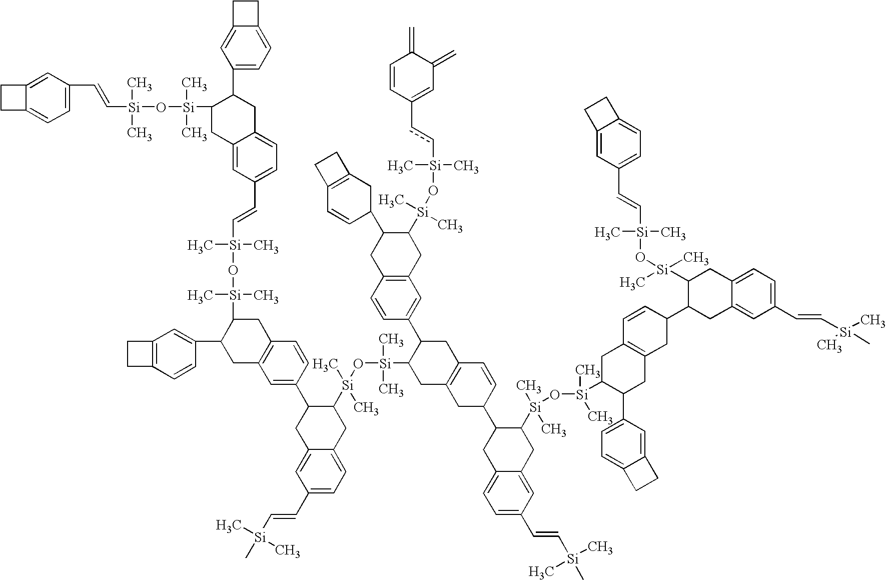

It has been proven that the BCB layer formed by plasma polymerization provides a high durability against thermal degradation at a temperature of not less than 400.degree. .C., as well as increased chemical stability and sufficient mechanical strength.

After formation of the BCB layer 110, the MSQ layer 112 is deposited thereon. The MSQ layer 112 is formed by spin coating.

Through the foregoing process the interconnect structure shown in FIG. 4 is formed. Adopting such interconnect structure facilitates formation of a highly reliable device structure.

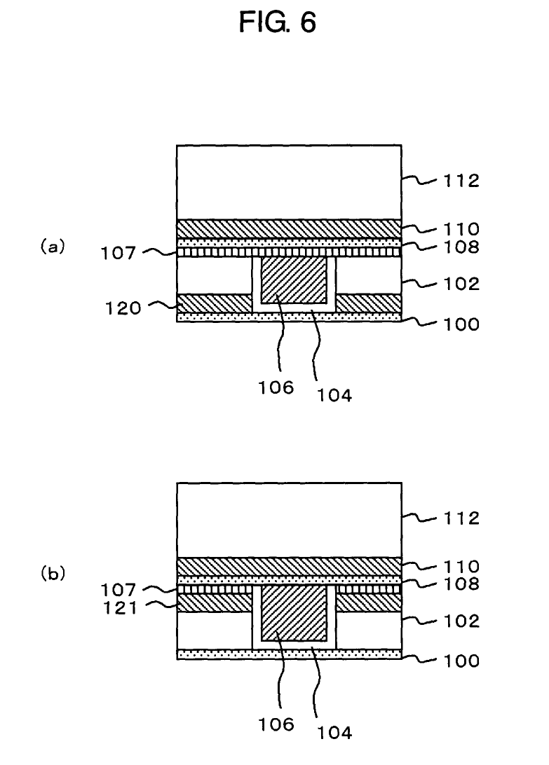

Further, in addition to the BCB layer provided between the SiCN layer 108 and the MSQ layer 112 as shown in FIG. 4, a constituted byBCB layer may be provided between the SiCN layer 100 and the MSQ layer 102, or between the MSQ layer 102 and the SiO.sub.2 layer 107. The above-mentioned interconnect structure is shown in FIGS. 6A and 6B.

Second Embodiment

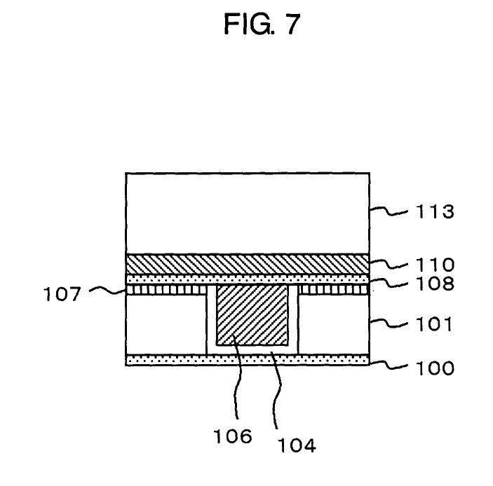

In a second embodiment, an SiOC layer is employed as a low dielectric layer of low dielectric constant material. FIG. 7 is a schematic cross-sectional view of an interconnect structure according to this embodiment. As shown, an SiOC layer 101, SiO.sub.2 layer 107, SiCN layer 108, BCB layer 110 and another SiOC layer 113 are deposited in this sequence on an SiCN layer 100, and a copper interconnect line constituted by a barrier metal layer 104 and a copper layer 106 is formed in an interconnect trench provided in the SiOC layer 101 and the SiO.sub.2 layer 107. Thickness of the respective layers of the interconnect structure shown in FIG. 4 may, for example, be as follows:

SiCN layer 100 20 to 100 nm

SiOC layer 101 200 to 400 nm

SiO.sub.2 layer 107 50 to 200 nm

copper layer 106 200 to 400 nm

SiCN layer 108 20 to 100 nm

BCB layer 110 20 to 200 nm

SiOC layer 113 300 to 1000 nm

Since the BCB layer 110 is highly adhesive to both of the SiCN layer 108 and the SiOC layer 113, weak adhesion, conventionally observed, between the SiCN layer 108 and the SiOC layer 113 can be avoided.

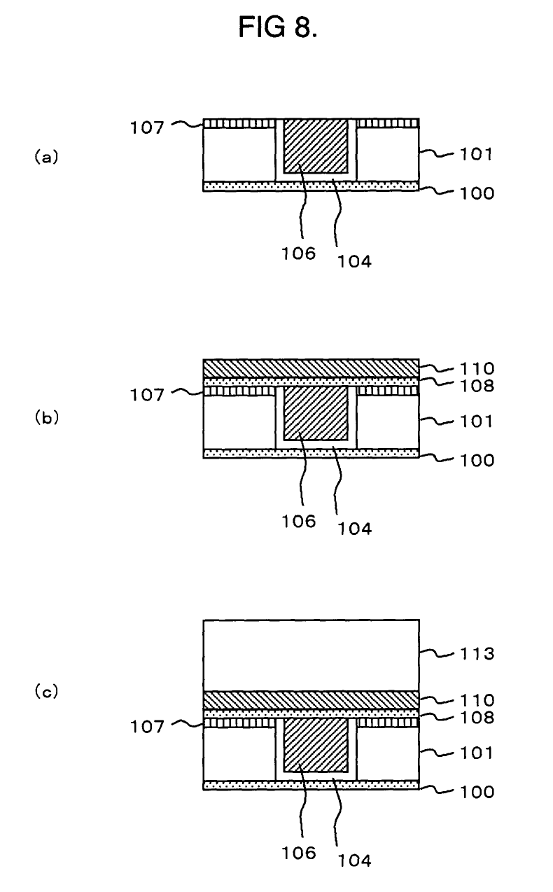

Referring to FIG. 8, a method of manufacturing the above interconnect structure will be described. As shown in FIG. 8A, the SiCN layer 100, SiOC layer 101 and SiO.sub.2 layer 107 are first formed in this sequence, and then, the copper interconnect line, constituted by the barrier metal layer 104 formed by depositing TaN and Ta in this order and the copper layer 106, are formed using the known Damascene process. The reason why the SiO.sus.2 layer 107 is provided is that adhesion between the copper diffusion barrier (the SiCN layer 108 in this embodiment) and a structure below the barrier needs to be increased and damage imposed on the MSQ layer 102 and caused by plasma charging during a resist ashing process needs to be avoided. Then, the SiCN layer 108, and the BCB layer 110 are deposited on the SiO.sub.2 layer 107 in this sequence (FIG. 8B). The BCB layer 110 is to be formed in the same manner as that explained in the description of the first embodiment. Thereafter, the SiOC layer 113 is formed on the BCB layer 110 (FIG. 8C) using plasma CVD method. In this case, it is preferable to use as a source gas a mixture of monosilane (SiH.sub.4) gas, alkysilane gas and oxidative gases. The alkysilane gas may be, for example, monomethylsilane, dimethylsilane, trimethylsilane, or tetramethylsilane, and one of those gases may singly be used or combination of two or more of those gases may be used. Among those gases, the trimethylsilane is preferably employed. In this case, the term “oxidative gas” refers to gas that acts to oxidize alkysilane and is realized by employing gas having an oxygen element in its molecules. For example, one or more chosen out of a group consisting of NO, N.sub.2O, CO, CO.sub.2 and O.sub.2 can be employed, and in terms of ability to appropriately oxidize an object, it is preferable to use O.sub.2 or N.sub.2O. In this embodiment, a mixture of trimethylsilane and O.sub.2 is employed as source gas. The interconnect structure of FIG. 7 is thus formed.

Since the SiOC film constituting the SiOC layer 101 and the SiOC layer 113 is hydrophobic like the MSQ used in the first embodiment, adhesion to insulating films adjacent the SiOC layer becomes weak in some cases. According to this embodiment, however, since the BCB layer formed by plasma polymerization is disposed between the SiOC layer and the adjacent layers, adhesion between the interlayer dielectric films is significantly enhanced. Further, although in this embodiment, the BCB layer 110 is disposed between the SiCN layer 108 and the SiOC layer 113, a BCB layer may additionally be provided between the SiCN layer 100 and the SiOC layer 101.

Third Embodiment

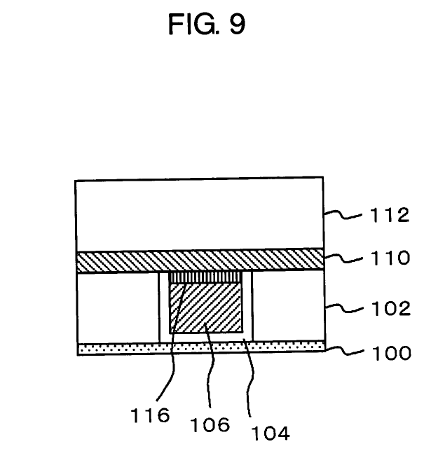

In the embodiment, a BCB layer is provided as a cap metal film in an upper portion of the copper interconnect line in an interconnect structure. The interconnect structure according to the embodiment is shown in FIG. 9. As shown, an MSQ layer 102, BCB layer 11O and another MSQ layer 112 are deposited in this sequence on an SiCN layer 100, and a copper interconnect line constituted by a barrier metal layer 104 and a copper layer 106 is formed in the MSQ layer 102.

A cap metal 116 is formed atop the copper layer 106. The cap metal 116 is made of a metal material having better electromigration characteristics than copper, and serves to reduce diffusion of copper into the interlayer dielectric film and thus to prevent void formation due to stress migration of a material that makes up the copper interconnect line. For example, electroless nickel alloy or electroless cobalt alloy may be a material making up the cap metal 116 and in this case, the material may appropriately contain boron or phosphor. Alternatively, silver-copper alloy may be employed as the cap metal.

Unlike the interconnect structures shown in FIGS. 4, 6 and 7, the interconnect structure of FIG. 9 is not provided with the SiCN layer 108 serving as a copper diffusion barrier, but instead, is provided with the BCB layer 110 directly overlying the copper interconnect line. In this embodiment, since the cap metal 116 substantially reduces the degree to which copper is diffused to associated portions, the cap metal 116 and the BCB layer 110 cooperatively prevents the copper diffusion. Accordingly, the SiCN layer 108 provided in the interconnect structure of FIG. 4 needs not be formed in the embodiment. In a conventional structure in which the SiCN layer 108 is provided, parasitic capacitance between adjacent interconnects is prone to increase unfavorably introducing interconnect delay because of a high dielectric constant of the SiCN. Employment of the interconnect structure according to the embodiment provides a solution to such problem and a device that operates at higher speed and with higher reliability.

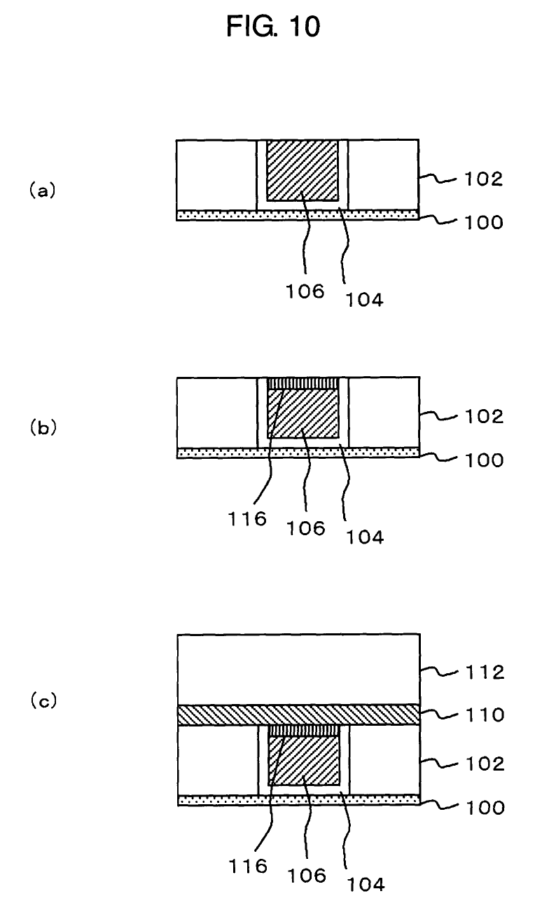

Referring to FIG. 10, a method of manufacturing the above interconnect structure will be described. After the MSQ layer 102 is formed on the SiCN layer 100, the copper interconnect line constituted by the barrier metal layer 104 and the copper layer 106 are formed using the known damascene process (FIG. 10A). Then the cap metal 116 is selectively formed on the copper layer 106 by electroless selective plating (FIG. 10B). The cap metal 116 is realized by employment of CoWP, CoB or NiB.

Then, the BCB layer 110 is formed by plasma polymerization and the MSQ layer 112 is formed thereon by spin coating (FIG. 10C). The interconnect structure shown in FIG. 9 is thus obtained.

### EXAMPLE

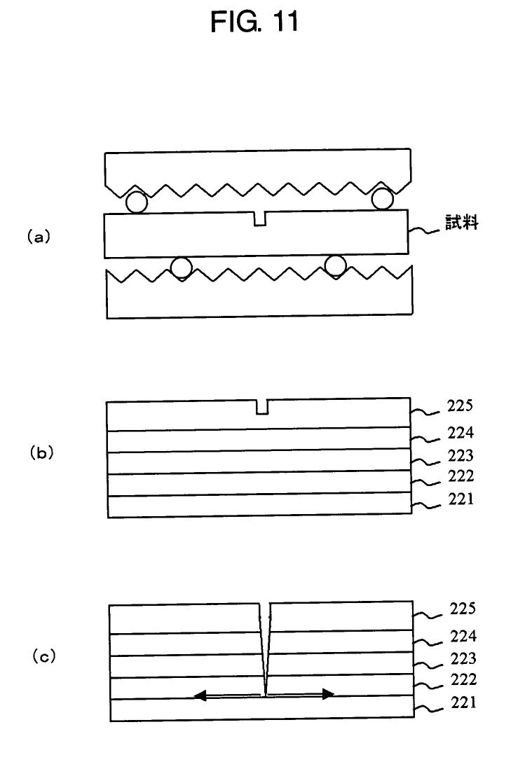

Adhesion between the MSQ layer and insulating layers adjacent the MSQ layer has been evaluated through a four-point bending test. FIG. 11A shows an illustration of how the sample to be tested was placed during the four-point bending test executed in the example. A sample was placed on a retainer having four supporting points. FIG. 11B is a schematic cross-sectional view of the sample. An MSQ layer 222, a silicon oxide layer 223, an epoxy layer 224 and a silicon layer 225 were laminated in this sequence on a substrate 221. A notch was introduced in a central portion of the silicon layer 225. When a load was imposed on the sample, a crack originating from the notch to a point on the substrate 221, from which point the crack further runs horizontally along an interface of the MSQ layer 222 and the substrate 221. Then, adhesion between the substrate 221 and the MSQ layer 222 was evaluated based on the load applied at this moment.

The substrate 221 was constructed such that the SiCN layer was formed on a silicon substrate and a BCB layer was formed thereon in an appropriate manner. The sample No.1 was prepared such that a BCB layer was formed on the SiCN layer by plasma polymerization and the BCB layer was subjected to the UV treatment, and then, the MSQ layer 222 was formed thereon. During the UV treatment, UV ray was irradiated by a UV lamp for approx. 10 seconds under a room temperature atmosphere. The sample No.2 was prepared such that a BCB layer was formed on the SiCN layer by plasma polymerization and without through the UV treatment, the MSQ layer 222 was formed on the BCB layer. The sample No.3 was prepared such that the MSQ layer 222 was formed directly on the SiCN layer. The BCB layers are formed in a manner similar to that explained in the description of the first embodiment. That is, the divinylsiloxane benzocyclobutene monomer was vaporized and introduced into plasma in, for example, He to perform plasma polymerization, thereby producing the BCB layer. In this case, the BCB monomer was vaporized at a temperature of 200.degree. .C. and the monomer was supplied with a He carrier gas at a flow rate of 500 sccm to a reaction chamber and BCB monomer gas was introduced into He plasma atmosphere within the chamber through a shower head to which an RF power of 13.56 MHz was applied, and then, a plasma-polymerized BCB layer was grown on a substrate heated to 400.degree. C.. Formation of the BCB layer through the above-mentioned plasma polymerization was ensured by measurement of the BCB layer using a Fourier transform infrared spectrometer.

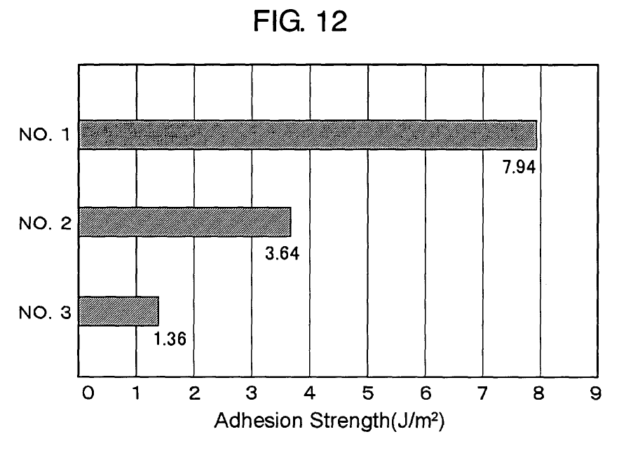

FIG. 12 shows results obtained by evaluating the adhesion between the substrate 221 and the MSQ layer 222, with respect to the samples No.1 to No.3. It will be obvious to those skilled in the art that formation of a BCB layer between the associated layers in the interconnect structure enhances adhesion between the layers to be contact with each other in the conventional interconnect structure, and the UV-treated BCB layer further enhances the adhesion. It should be noted that although the sample No.1 was subjected to UV treatment, the sample may be subjected to plasma treatment in a nitrogen or hydrogen plasma atmosphere, producing beneficial effects similar to those observed using UV treatment. In addition, the sample may preferably be subjected to treatment in a plasma containing oxygen or N.sub.2O for lightly oxidizing a surface portion of the BCB layer.

As described above, the invention provides a lamination comprising an adhesive film constituted by a silicon-based compound having an aromatic ring in a molecule thereof, and a low dielectric constant film made of an organic low dielectric constant material having a specific dielectric constant not greater than 4 and formed in contact with the adhesive film. Therefore adhesion, which is problematic in the conventional interconnect stack, between a low dielectric constant film and the layers to be contact with the low dielectric constant film can significantly be enhanced.

What is claimed is:

1. A semiconductor device comprising a semiconductor substrate and an interlayer dielectric film formed on said semiconductor substrate, said interlayer dielectric film including a lamination consisting essentially of an adhesive film constituted essentially by a silicon-based compound having an aromatic ring in a molecule of said silicon-based compound and a low dielectric constant film constituted essentially by an organic low dielectric constant material having a specific dielectric constant not greater than 4 and contacting said adhesive film.

2. The semiconductor device as set forth in claim 1, wherein said aromatic ring is a fused ring.

3. The semiconductor device as set forth in claim 1, wherein said silicon-based compound includes a benzocyclobutene unit in a molecule thereof.

4. The semiconductor device as set forth in claim 1, wherein said silicon-based compound contains a silylene unit in a molecule thereof.

5. The semiconductor device as set forth in claim 1, wherein said silicon-based compound is a polymer formed through polymerization of a monomer containing a divinylsiloxane bisbenzocyclobutene unit.

6. The semiconductor device as set forth in claim 5, wherein said silicon-based compound is a polymer formed through plasma polymerization of said monomer.

7. The semiconductor device as set forth in claim 1, wherein said organic low dielectric constant material does not contain an Si—H bond.

8. The semiconductor device as set forth in claim 7, wherein said organic low dielectric constant material is one of methylsilsesquioxane and SiOC.

9. The semiconductor device as set forth in claim 1, wherein said lamination is formed by depositing said adhesive film and said low dielectric constant film in this sequence.

10. The semiconductor device as set forth in claim 1, further comprising a metal wiring formed on said semiconductor substrate, wherein said lamination is formed on said metal wiring.

11. The semiconductor device as set forth in claim 10, wherein said adhesive film is formed in contact with said metal wiring, and further said low dielectric constant film is formed on said adhesive film.

12. The semiconductor device as set forth in claim 10, wherein said metal diffusion barrier is formed on said metal wiring, and said adhesive film and said low dielectric constant film are formed in this sequence on said metal diffusion barrier.

13. The semiconductor device as set forth in claim 10, wherein a cap metal is provided on an upper surface of said metal wiring, and said adhesive film is formed in contact with said upper surface of said cap metal.

14. A method of manufacturing a semiconductor device, comprising: forming on a semiconductor substrate an adhesive film constituted essentially by a silicon-based compound having an aromatic ring in a molecule thereof; and forming a low dielectric constant film constituted essentially by an organic low dielectric constant material having a specific dielectric constant not greater than 4 over said adhesive film.

15. The manufacturing method as set forth in claim 14, further comprising: performing UV treatment or plasma treatment of said adhesive film after the step of forming said adhesive film, and performing the step of forming said low dielectric constant film.

16. The manufacturing method as set forth in claim 14, further comprising: forming a metal wiring on said semiconductor substrate, and subsequently performing the step of forming said adhesive film.

17. The manufacturing method as set forth in claim 14, further comprising: forming a metal diffusion barrier on said metal wiring between the step of forming said metal wiring and the step of forming said adhesive film.

18. The manufacturing method as set forth in claim 14, further comprising: forming a cap metal on an upper surface of said metal wiring; and forming said adhesive film in contact with an upper surface of said cap metal.

19. A method of manufacturing a semiconductor device comprising: forming on a semiconductor substrate a low dielectric constant film constituted essentially by an organic low dielectric constant material having a specific dielectric constant not greater than 4; and forming an adhesive film constituted essentially by a silicon-based compound having an aromatic ring in a molecule thereof over said low dielectric constant film.

20. The manufacturing method as set forth in claim 19, wherein the step of forming said adhesive film includes the step of polymerizing a monomer containing a divinylsiloxane bisbenzocyclobutene unit and said polymerizing is plasma polymerization.

21. The manufacturing method as set forth in claim 14, wherein said organic low dielectric constant material does not contain an Si—H bond.

22. The manufacturing method as set forth in claim 19, wherein said organic low dielectric constant material does not contain an Si—H bond.

23. The manufacturing method as set forth in claim 21, wherein said organic low dielectric constant material is one of methylsilsesquioxane and SiOC.

24. The manufacturing method as set forth in claim 22, wherein said organic low dielectric constant material is one of methylsilsesquioxane and SiOC.
